(19) United States
(12) Patent Application Publication
(10) Pub. No.: US 2018/0323096 A1
(43) Pub. Date: Nov. 8, 2018

(54) SYSTEMS AND METHODS FOR PASSIVE ALIGNMENT OF SEMICONDUCTOR WAFERS

(71) Applicant: BOARD OF REGENTS, THE UNIVERSITY OF TEXAS SYSTEM, Austin, TX (US)

(72) Inventors: Michael CULLINAN, Austin, TX (US); Andrew DUENNER, Houston, TX (US)

(21) Appl. No.: 15/773,410

(22) PCT Filed: Nov. 3, 2016
(86) PCT No.: PCT/US2016/060236

§ 371 Date: May 3, 2018

Related U.S. Application Data
(60) Provisional application No. 62/250,468, filed on Nov. 3, 2015.

(51) Int. Cl. H01L 21/68; H01L 21/687

(52) U.S. Cl. CPC H01L 21/68; H01L 21/68728

(57) ABSTRACT

An example passive wafer alignment device can include a stage for holding a wafer, a plurality of pins arranged on the stage, the pins being arranged to contact respective portions of the wafer, and a preload device arranged on the stage. The preload device can be configured to apply a preload force to the wafer. In addition, two of the pins can be arranged to contact respective portions of a flat edge of the wafer, and a third pin and the preload device can be arranged to contact respective portions of a curved edge of the wafer. The third pin and the preload device can be arranged at respective locations on the stage to optimally constrain the wafer to the stage.

### CROSS-REFERENCE TO RELATED APPLICATIONS

This application claims the benefit of U.S. Provisional Patent Application No. 62/250,468, filed on Nov. 3, 2015, entitled “SYSTEMS AND METHODS FOR PASSIVE ALIGNMENT OF SEMICONDUCTOR WAFERS,” the disclosure of which is expressly incorporated herein by reference in its entirety.

### STATEMENT REGARDING FEDERALLY FUNDED RESEARCH

This invention was made with government support under Grant no. EEC1160494 awarded by the National Science Foundation. The government has certain rights in the invention.

### BACKGROUND

Recent advancements in metrology and nanofabrication systems have created a demand for wafer alignment mechanisms with positioning repeatability on the order of microns to tens of microns. Conventional techniques for passive wafer alignment are time consuming, inaccurate or impractical. For example, optical alignment systems are time consuming to use. Alignment systems that rely on MEMS-based structures on the wafer are impractical for most applications. Conventional alignment mechanisms that use pin constraints also have a tendency to jam.

One of the major challenges in nanoscale manufacturing is defect control. Optical inspection is not an option at the nanoscale level due to the diffraction limit of light, and without inspection high scrap rates can occur. One solution to this problem is inline metrology using atomic force microscopes. Single chip MEMS-based atomic force microscopes (AFMs) have been developed that could be incorporated into fabrication lines. However, metrology with these AFM chips requires accurate placement of specimens relative to the AFM tip. Further, present set up times for an AFM are on the order of thirty minutes.

Conventional passive wafer alignment mechanisms typically consist of a stage with three pins and a nesting force in contact with a wafer. Typically, two pins are in contact with the main flat on the wafer. One conventional design references restoring moments when justifying the location of the third pin, but the position of the nesting force (e.g., preload force) is arbitrarily chosen. In addition, conventional passive wafer alignment systems tend to yield poor positioning repeatability.

### SUMMARY

Disclosed herein are devices and methods for passive alignment of semiconductor wafers. In accordance with the present disclosure, a mechanical wafer alignment device is provided that enables inline atomic force microscope (AFM) metrology in nanoscale manufacturing and reduces AFM metrology setup time. An example water alignment device can include three pins that constrain the wafer in six degrees of freedom and a nesting force applied by a flexure to keep the wafer in contact with the pins.

The devices and methods described herein are provided for rapid and repeatable passive alignment of samples such as silicon wafers. An example method comprises calculating optimal pin locations of three pins to exactly constrain an object in one plane and determining the ideal location of the third pin, as well as an ideal location of the nesting force, with respect to the edge of the object in contact with the two pins with parallel lines of action. An example wafer alignment device comprises three pins and a flexural bearing that applies a nesting force to keep the three pins in contact with the wafer. In order to increase repeatability out-of-plane each pin may have a taper so that the wafer is constrained in all six degrees of freedom. The nesting force can be applied by a flexural bearing designed to minimize jamming between the wafer and two pins.

An example passive wafer alignment device can include a stage for holding a wafer, a plurality of pins arranged on the stage, the pins being arranged to contact respective portions of the wafer, and a preload device arranged on the stage. The preload device can be configured to apply a preload force to the wafer. In addition, two of the pins can be arranged to contact respective portions of a flat edge of the wafer, and a third pin and the preload device can be arranged to contact respective portions of a curved edge of the wafer. The third pin and the preload device can be arranged at respective locations on the stage to optimally constrain the wafer to the stage.

Additionally, the respective locations on the stage for the third pin and the preload device can optimize a restoring moment about an instantaneous center of rotation (ICR) imposed by the preload force on the wafer. Optionally, the respective locations on the stage for the third pin and the preload device can maximize the restoring moment about the ICR imposed by the preload force on the wafer. For example, the restoring moment can be maximized as a function of a first angle formed between an axis of the wafer and the respective location of the third pin.

Additionally, the ICR imposed by the preload force on the wafer can be an intersection point between a line of action associated with the third pin and a line of action associated with one of the two pins. A line of action can be defined by a respective direction of a reaction force at a pin. Alternatively or additionally, respective lines of actions associated with the two pins can be approximately parallel.

Alternatively or additionally, the pins can optionally be tapered.

Alternatively or additionally, the preload device can optionally be a flexural bearing.

Another example passive wafer alignment device can include a stage for holding a wafer, a plurality of tapered pins arranged on the stage, the tapered pins being arranged to contact respective portions of the wafer, and a preload device arranged on the stage. The preload device can be configured to apply a preload force to the wafer.

Additionally, the tapered pins can optionally be configured to constrain the wafer to the stage via surface-to-surface contact.

Yet another example passive wafer alignment device can include a stage for holding a wafer, a plurality of pins arranged on the stage, the pins being arranged to contact respective portions of the wafer, and a flexural bearing arranged on the stage. The flexural bearing can be configured to apply a preload force to the wafer.

Additionally, the flexural bearing can optionally define a circular contact interface.

Alternatively or additionally, the flexural bearing can optionally be further configured to adjust the preload force applied to the wafer.

An example method for producing a passive wafer alignment device can include arranging a plurality of pins on a stage for holding a wafer, determining respective optimal locations on the stage for a third pin and a preload device for applying a preload force to the wafer, and arranging the third pin and the preload device at the respective optimal locations on the stage. In addition, two of the pins can be arranged to contact respective portions of a flat edge of the wafer, and the third pin and the preload device can be arranged to contact respective portions of a curved edge of the wafer.

Additionally, the step of determining respective optimal locations on the stage for a third pin and a preload device can include analyzing a plurality of reaction forces at each of the pins as a function of a first angle formed between an axis of the wafer and the respective optimal location of the third pin and a second angle formed between the axis of the wafer and the respective optimal location of the preload device. Additionally, the step of determining respective optimal locations on the stage for a third pin and a preload device can further include determining values of the first angle and the second angle that result in compressive reaction forces at the pins.

Alternatively or additionally, the step of determining respective optimal locations on the stage for a third pin and a preload device can include analyzing a restoring moment about an instantaneous center of rotation (ICR) imposed by the preload force on the wafer. Optionally, the step of determining respective optimal locations on the stage for a third pin and a preload device can include maximizing the restoring moment about the ICR imposed by the preload force on the wafer. Optionally, the restoring moment can be maximized as a function of a first angle formed between an axis of the wafer and the respective optimal location of the third pin.

Alternatively or additionally, the ICR imposed by the preload force on the wafer can be an intersection point between a line of action associated with the third pin and a line of action associated with one of the two pins. A line of action can be defined by a respective direction of a reaction force at a pin. Alternatively or additionally, respective lines of actions associated with the two pins can be approximately parallel.

Alternatively or additionally, the pins can optionally be tapered. For example, the pins can be configured to constrain the wafer to the stage via surface-to-surface contact.

Alternatively or additionally, the preload device can be a flexural bearing. Optionally, the flexural bearing can define a circular contact interface.

Alternatively or additionally, the preload device can optionally be further configured to adjust the preload force applied to the wafer.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

To facilitate an understanding of and for the purpose of illustrating the present disclosure, example features and implementations are disclosed in the accompanying drawings, it being understood, however, that the present disclosure is not limited to the precise arrangements and instrumentalities shown, and wherein similar reference characters denote similar elements throughout the several views, and wherein:

FIG. 1 illustrates an example metrology device according to implementations described herein.

FIG. 2 illustrates an example passive wafer alignment device according to implementations described herein.

FIG. 3 illustrates an example tapered pin according to implementations described herein.

FIG. 4 is a flow chart illustrating example operations for producing a passive wafer alignment device according to implementations described herein.

FIG. 5A illustrates a diagram of wafer alignment naming conventions in accordance with the present disclosure.

FIG. 5B illustrates a diagram of wafer instantaneous centers of rotation and orientation of nesting force moments in accordance with the present disclosure.

FIG. 6 illustrates a nesting force window plot in accordance with the present disclosure.

FIG. 7 is an example computing device.

FIG. 8 illustrates an experimental testing setup using an example wafer alignment device.

FIG. 9 shows a plot of translation repeatability results of the experiment conducted using the experimental testing setup of FIG. 8.

FIG. 10 shows a plot of rotation repeatability results of the experiment conducted using the experimental testing setup of FIG. 8.

FIG. 11 shows a plot of X-axis translational repeatability trial results of the experiment conducted using the experimental testing setup of FIG. 8.

FIG. 12 shows a plot of Y-axis translational repeatability trial results of the experiment conducted using the experimental testing setup of FIG. 8.

FIG. 13 shows a plot of angular repeatability trial results of the experiment conducted using the experimental testing setup of FIG. 8.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. This disclosure contemplates that the metrology devices and methods described herein can be used with nanoscale and/or microscale metrology applications such as atomic force microscopy, scanning tunneling microscopy, and/or nearfield optical scanning microscopy. The metrology devices and methods can be used to reduce setup time for nanoscale and/or microscale metrology applications.

In accordance with the present disclosure, a mechanical wafer alignment device (e.g., a passive wafer alignment device) is described. The wafer alignment device can include three pins and a nesting force applied by a preload device to keep a wafer in contact with the pins to restrain the wafer in six degrees of freedom. In certain embodiments, the kinematic coupling can be used to precisely mate the mechanical wafer alignment device below an XY precision stage that includes an array of Atomic Force Microscope (AFM) microchips. Using the mechanical wafer alignment device, one may achieve a wafer setup time of less than one minute and a lateral positioning accuracy on the order of 1 μm. In particular, the mechanical wafer alignment device disclosed herein can decrease setup times in AFM metrology. Translational positioning repeatability better than 2 μm and rotational repeatability better than 100 μrad can also be realized, for example. Sample setup times can be reduced to less than one minute, for example. The substantial time savings over traditional alignment methods as well as positioning repeatability well within the range of newly available AFM chips make the mechanical wafer alignment devices disclosed herein a suitable fixture for inline AFM metrology.

In accordance with the present disclosure, a method is also provided for determining optimal pin locations for three pins of a mechanical wafer alignment device. In particular, calculating optimal pin locations when using three pins to exactly constrain an object in one plane. Assuming that two pins are fixed with parallel lines of action, the method can determine suitable locations of the third pin and the nesting force (e.g., a preload force) with respect to the edge of the object in contact with the two pins with parallel lines of action. In accordance with the present disclosure, an optimal position of the third pin and an optimal position of the nesting force can be determined as function of a restoring moment imposed by the nesting force on the object. The restoring moment can be imposed about the finite instantaneous centers of the pin constraints with respect to each other. This moment can be, for example, a maximum magnitude and be in direction that would ensure that the object remains in contact with all three pins.

The method disclosed herein can be applied to the problem of, for example, passively aligning a wafer on a stage. The stage can comprise, for example, three pins and a preload device (e.g., a flexural bearing) that applies a nesting force (e.g., a preload force) in order to keep the three pins in contact with the wafer. Two of the pins in contact with the wafer can be located on the main flat of the wafer (also referred to herein as the “wafer flat”), for example. The method disclosed herein can be used to determine a suitable position for the third pin, as well as a suitable location of the preload device with respect to the wafer flat. The nesting force is applied by a flexural bearing which was designed to minimize jamming between the wafer and two pins.

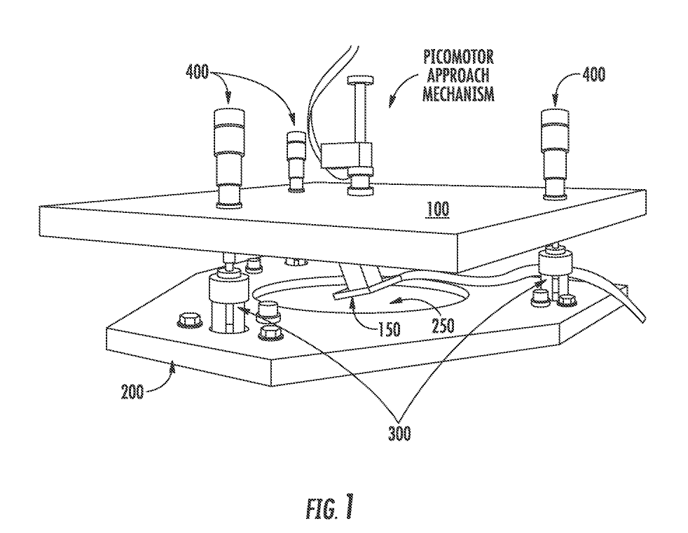

Referring now to FIG. 1, an example metrology device is shown. The metrology device can include an XY precision stage 100 including a microelectromechanical (MEMS) device 150 having a probe, and a sample stage 200 (also referred to herein as a “stage”) configured to hold a sample or specimen 250. This disclosure contemplates that the probe of the MEMS device 150 can optionally be a piezoelectric cantilever tip of the MEMS device. Optionally, the MEMS device can be an atomic force microscopy (AFM) chip or a scanning probe microscopy (SPM) chip. It should be understood that the MEMS device is not limited to AFM and SPM chips. As described above, the metrology systems and methods described herein can be used in other metrology applications. Optionally, the sample can be a semiconductor wafer. It should be understood that the sample is not limited to being semiconductor wafer. The metrology device can also include a kinematic coupler 300 for constraining the XY precision stage 100 in a fixed position relative to the sample stage 200. As shown in FIG. 1, the probe of the MEMS device 150 is aligned with a portion of the sample 250 when the XY precision stage 100 is constrained in the fixed position relative to the sample stage 200.

The kinematic coupler 300 can optionally be configured to constrain the first stage 100 in six degrees of freedom. The kinematic coupler 300 can optionally constrain the XY precision stage 100 in the fixed position relative to the sample stage 200 using a magnetic force (e.g., using magnets) and/or using the force of gravity. This disclosure contemplates that the kinematic coupler 300 can include at least one fastener and a corresponding groove, where the fastener interfaces with the corresponding groove such that the XY precision stage 100 is constrained in the fixed position relative to the sample stage 200.

The metrology device can also optionally include a plurality of micrometers 400. The micrometers 400 can be attached to the XY precision stage 100. Additionally, the micrometers 400 can be configured to adjust the position of the XY precision stage 100 relative to the sample stage 200. The micrometers can be used to make fine adjustments to the position of the XY precision stage 100 relative to the sample stage 200. For example, one or more micrometers can be used to adjust the position of the XY precision stage 100 relative to the second stage 200 in an out-of-plane direction (e.g., the Z-direction or Z-axis translation). As described below, in some implementations, the XY precision stage 100 defines a two-dimensional plane (e.g., the X-Y plane). Accordingly, displacements or translations in an X-direction and/or a Y-direction are referred to herein as the in-plane directions and displacements or translations in a Z-direction, which are orthogonal to the X- and Y-directions, are referred to as the out-of-plane direction. Alternatively or additionally, one or more micrometers can be used to adjust X-axis or Y-axis rotation. Optionally, after a fixed position is established (e.g., using a first sample), the micrometers 400 can be locked, and the XY precision stage 100 can be repeatedly removed from and returned to the fixed position relative to the sample stage 200 using the kinematic coupler 300.

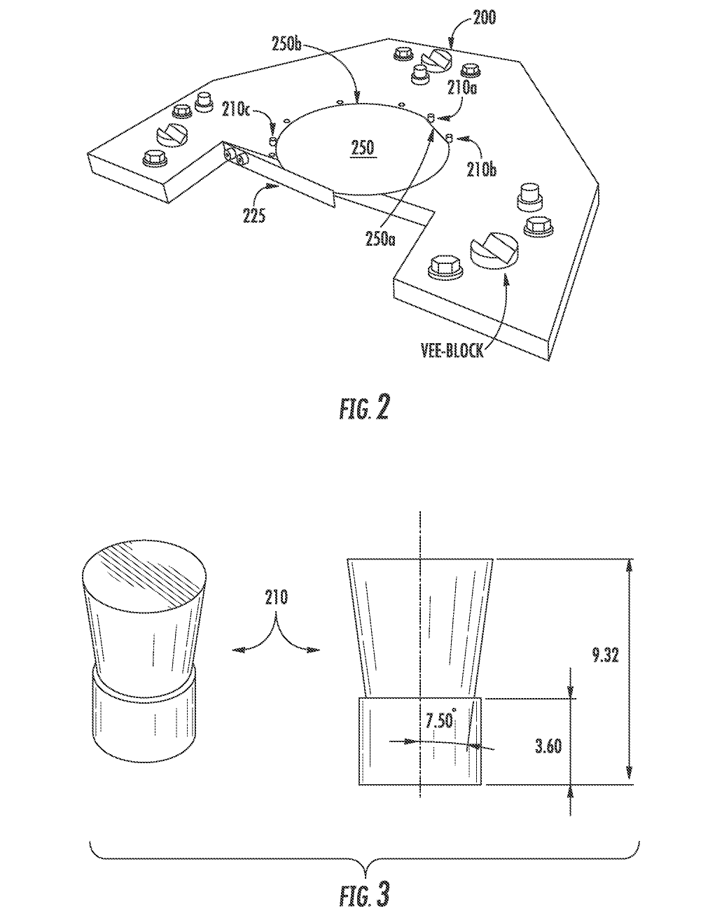

Referring now to FIG. 2, an example passive wafer alignment device is shown. The passive wafer alignment device can include a stage 200 for holding a sample 250 (e.g., a wafer), a plurality of pins 210a-c (collectively referred to herein as “pins 210”) arranged on the stage 200, and a preload device 225 arranged on the stage 200. The preload device 225 can be configured to apply a preload force to the wafer. As shown in FIG. 2, the pins 210 are arranged to contact respective portions of the wafer. For example, two of the pins 210a and 210b can be arranged to contact respective portions of the wafer flat 250a (e.g., a flat edge of the wafer). The wafer flat can be used to orient the wafer with respect to various equipment, for example. Pins 210a and 210b are sometimes referred to herein as right pin and left pin, respectively. A third pin 210c and the preload device 225 can be arranged to contact respective portions of a curved edge of the wafer 250b, i.e., not along the wafer flat.

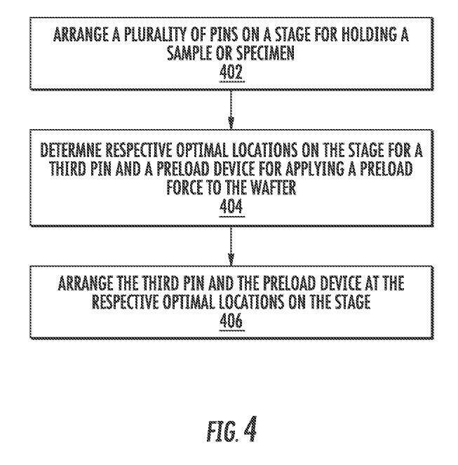

In some implementations, the pins 210 can optionally be tapered, for example. For example, the pins 210 can be configured to constrain the wafer to the stage via surface-to-surface contact. An example tapered pin 210 is shown in FIG. 3. In order to increase repeatability out-of-plane, each pin 210 can include a taper, which constrain six degrees of freedom (DOF) of the wafer. Tapered pins are commonly used to align two features in an assembly with the tapered pins fitting into tapered holes. The use of tapered pins in the wafer alignment device is unique in that tapered pins can be used to constrain an object via surface-to-surface contact. The taper of the pins 210 is configured so that a wafer surface can be maintained parallel to the base of the alignment mechanism (e.g., the stage 200).

Referring again to FIG. 1, in some implementations, the preload device 225 can optionally be a flexural bearing as shown in FIG. 1. The wafer is compliant only in the direction towards the optimal location of the preload force (e.g., the nesting force). Conventional technologies do not focus on the nesting force as a potential source of jamming. The wafer alignment device described herein including a flexural bearing as the preload device reduces the potential for jamming through design of the flexure bearing and the use of a circular contact interface between the flexure bearing and the wafer. As shown in FIG. 1, the flexural bearing is mounted to ground via screws in slots. The slots allow for adjustment of the preload load force applied to the wafer so that a known nesting force can be precisely and repeatably applied to the wafer.

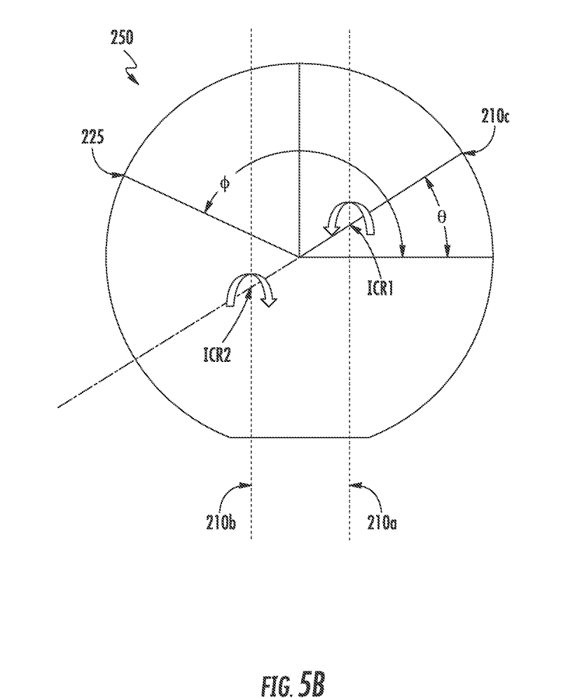

In some implementations, as described herein, the third pin 210c and the preload device 225 can be arranged at respective locations on the stage 200 to optimally constrain the wafer to the stage. As described herein, the respective locations on the stage 200 for the third pin 210c and the preload device 225 can optimize a restoring moment about an instantaneous center of rotation (ICR) imposed by the preload force on the sample 250 (e.g., a wafer). ICRs are described below with regard to FIG. 5B. Optionally, the respective locations on the stage 200 for the third pin 210c and the preload device 225 can maximize the restoring moment about the ICR imposed by the preload force on the sample 250 (e.g., a wafer). For example, the restoring moment can be maximized as a function of a first angle (e.g., θ in FIG. 5A) formed between an axis of the sample 250 (e.g., the X-axis in FIG. 5A) and the respective location of the third pin. Additionally, the ICR imposed by the preload force on the sample 250 (e.g., a wafer) can be an intersection point between a line of action associated with the third pin 210c and a line of action associated with one of the two pins 210a and/or 210b. A line of action can be defined by a respective direction of a reaction force at a pin (e.g., as shown in FIGS. 5A-b). Alternatively or additionally, respective lines of actions associated with the two pins 210a, 210b can be approximately parallel (e.g., as shown in FIGS. 5A-b).

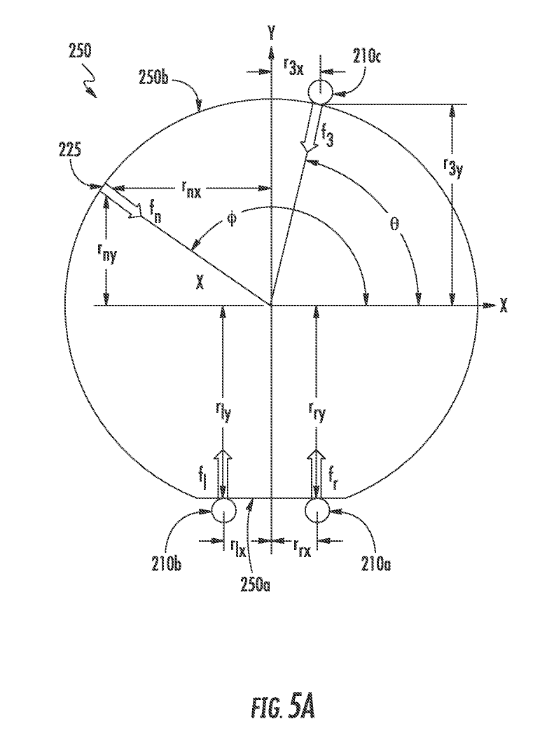

Referring now to FIG. 4, example operations for producing a passive wafer alignment device are shown. At 402, a plurality of pins (e.g., pins 210 of FIGS. 2-3) are arranged on a stage (e.g., stage 200 of FIGS. 1 and 2) for holding a sample or specimen (e.g., a wafer). At 404, respective optimal locations on the stage for a third pin (e.g., pin 210c of FIG. 2) and a preload device (e.g., preload device 225 of FIG. 2) for applying a preload force to the wafer are determined. At 406, the third pin (e.g., pin 210c of FIG. 2) and the preload device (e.g., preload device 225 of FIG. 2) are arranged at the respective optimal locations on the stage (e.g., stage 200 of FIGS. 1 and 2). As described herein, two of the pins (e.g., pins 210a and 210b of FIG. 2) can be arranged to contact respective portions of the wafer flat. The third pin (e.g., pin 210c of FIG. 2) and the preload device (e.g., preload device 225 of FIG. 2) can be arranged to contact respective portions of a curved edge of the wafer, i.e., not along the wafer flat.

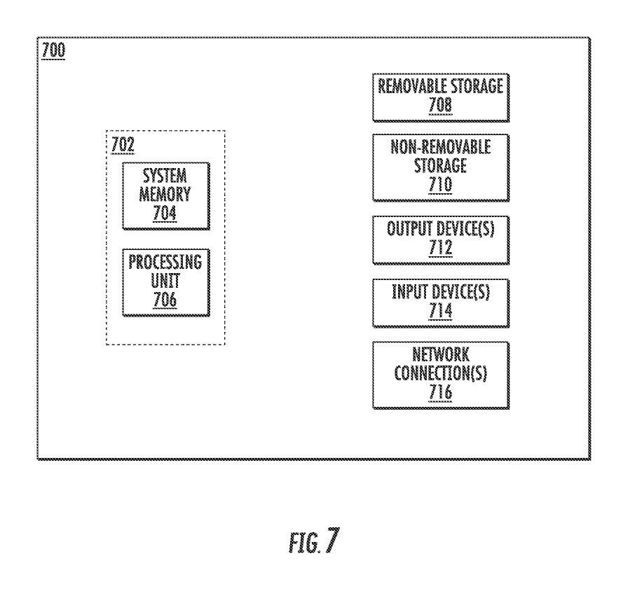

This disclosure contemplates that the optimal locations can be determined (e.g., step 404 of FIG. 4) using software and/or hardware (e.g., computing device 700 of FIG. 7) according to the techniques described herein. Additionally, the step of determining respective optimal locations on the stage for a third pin and a preload device can include analyzing a plurality of reaction forces at each of the pins as a function of a first angle (e.g., θ in FIG. 5A) formed between an axis of the sample 250 (e.g., the X-axis in FIG. 5A) and the respective location of the third pin and a second angle (e.g., ϕ in FIG. 5A) formed between the axis of the sample 250 (e.g., the X-axis in FIG. 5A) and the respective optimal location of the preload device. Additionally, the step of determining respective optimal locations on the stage for a third pin and a preload device can further include determining values of the first angle (e.g., θ in FIG. 5A) and the second angle (e.g., ϕ in FIG. 5A) that result in compressive reaction forces at the pins.

Alternatively or additionally, the step of determining respective optimal locations on the stage for a third pin and a preload device can include analyzing a restoring moment about an ICR imposed by the preload force on the wafer. ICRs are described below with regard to FIG. 5B. Optionally, the step of determining respective optimal locations on the stage for a third pin and a preload device can include maximizing the restoring moment about the ICR imposed by the preload force on the wafer. Optionally, the restoring moment can be maximized as a function of a first angle (e.g., θ in FIG. 5A) formed between an axis of the sample 250 (e.g., the X-axis in FIG. 5A) and the respective location of the third pin.

Alternatively or additionally, the ICR imposed by the preload force on the sample 250 (e.g., a wafer) can be an intersection point between a line of action associated with the third pin 210c and a line of action associated with one of the two pins 210a and/or 210b. A line of action can be defined by a respective direction of a reaction force at a pin (e.g., as shown in FIGS. 5A-b). Alternatively or additionally, respective lines of actions associated with the two pins 210a, 210b can be approximately parallel (e.g., as shown in FIGS. 5A-b).

Design and Optimization

A wafer in contact with a flat surface has three degrees of freedom—two translational and one rotational. Out of plane rotations and translation are thought to be sufficiently limited by the gravitational force on the wafer. Three pin constraints can be used to exactly constrain the wafer such that it has zero degrees of freedom. Two pins with intersecting lines of action (LOAs) constrain the translational degrees of freedom of the wafer. A third pin is used to constrain rotation of the wafer and its location is not trivial. Rigid bodies rotate about instantaneous centers located at the intersections of the LOAs of constraints. Thus, in order to constrain a rotational degree of freedom, two of the three constraints must be parallel, thereby forming an instantaneous center at infinity that prevents rotation. Conventional wafers possess a flat (e.g., the wafer flat or a flat edge of the wafer) which provides a convenient location for the constraints with parallel LOAs.

A nesting force (e.g., a preload force) can be applied by any suitable force applicator (e.g., a preload device such as a flexure bearing) to maintain contact between the wafer and the pins. As described above, a flexure bearing can be used to apply the preload force or nesting force. Using a flexural bearing to apply preload force can reduce the potential for jamming through design of the flexure and the use of a circular contact interface between the flexure and the wafer. The flexural bearing described herein can be mounted to ground via screws in slots, which allow for adjustment of the preload force applied to the wafer so that a known preload force can be precisely and repeatedly applied to the wafer.

Referring now to FIG. 5A, a diagram illustrating wafer alignment naming conventions in accordance with the present disclosure shown. In the environment of the passive water alignment device, the preload device 225 applies a nesting force Fₙ at an angle ϕ measured with respect to the x-axis of the sample 250. The pins 210b and 210a in contact with the flat of the wafer are referred to as ‘left pin’ and ‘right pin’, respectively. The third pin 210c is referred to as ‘third pin’ and makes an angle θ with respect to the x-axis.

In accordance with the present disclosure, an example method for optimizing constraint locations of pins can include analyzing reaction forces (e.g., fᵣ, fₗ, f₃) and moments as a function of the unknown angles θ and ϕ. Reaction forces at each pin can be determined, for example, using matrix inversion to satisfy static equilibrium of forces in the x-y plane and equilibrium of moments about the z-axis. Exemplary reaction forces at each of the three pins are shown in Equation 1 below.

$$[ \begin{matrix}{f}_{3} \\ {f}_{l} \\ {f}_{r}\end{matrix} ] = {f}_{n} [ \begin{matrix}- cos φ sec θ \\ \frac{1}{2} ( sin φ - cos φ tan θ ) \\ \frac{1}{2} ( sin φ - cos φ tan θ )\end{matrix} ] \qquad ( 1 )$$

Allowable combinations of ϕ and θ for a given wafer geometry can include those resulting in compressive reaction forces (e.g., positive values). Compressive reaction forces are needed to maintain the sample 250 (e.g., a wafer) in static equilibrium. From this constraint it is evident that for three pin environments, ϕ and θ must be on opposite sides of an imaginary vertical line drawn between the left pin 210b and the right pin 210a. FIGS. 5A-5B show an example nesting force (e.g., preload force) being applied on the left hand side of the vertical line and an example third pin location residing on the right hand side of the vertical line. It should be understood that the nesting force (e.g., preload force) can also be applied on the right hand side of the vertical line with the third pin can be located on the left hand side of the vertical line.

The intersections between pin lines of action constitute wafer instantaneous centers of rotation (ICRs). A line of action can be defined by a respective direction of a reaction force at a pin (e.g., defined by the directions of fᵣ, fₗ, f₃ as shown in FIGS. 5A-b). As shown in FIGS. 5A-5B, respective lines of actions associated with the two pins 210a, 210b can be approximately parallel. The moment of the nesting force about each ICR, for a wafer in contact with only the pins with lines of action that intersect at that ICR, must be in the direction of the pin that is not in contact with the wafer. FIG. 5B illustrates an example of wafer instantaneous centers of rotation as well as exemplary orientation of nesting force moments about the ICRs. Equation 2 below shows the nesting force moment about ICR1 as a function of ϕ and θ.

$${M}_{ICR 1} = - \frac{1}{2} {F}_{n} ( {r}_{rx} - {r}_{lx} ) * sec θ * sin ( θ - φ ) \qquad ( 2 )$$

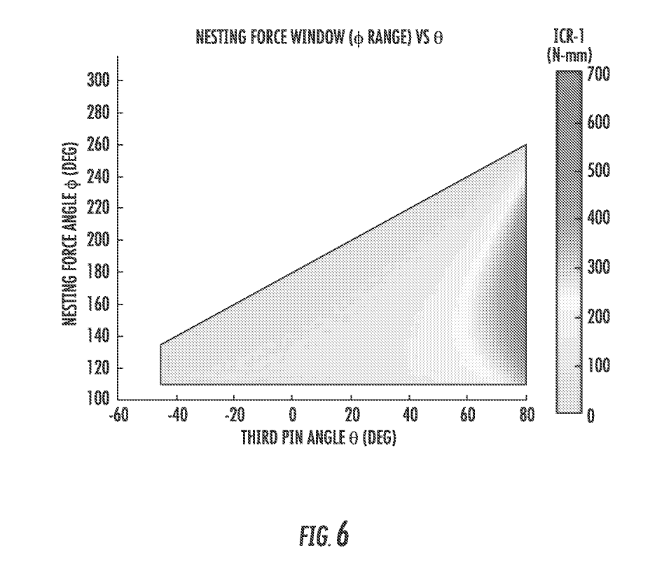

The nesting force moment is shown to be a function of (a) the magnitude of the nesting force, (b) the distance between the pins located on the wafer flat (e.g., pins 210a, 210b in FIGS. 5A-5B), and (c) angles ϕ and θ. By symmetry and choice of coordinate system, the two nesting force moments are equal in magnitude and opposite in direction. In order to increase the magnitude of the nesting force moments, the distance between the pins in contact with the wafer flat can be maximized. Maximizing the magnitude of the nesting force also increases the magnitude of the nesting force moments. An example plot of nesting force as a function of the angles ϕ and θ is shown in FIG. 6, which gives insight into suitable optimal positions of the preload device 225 and third pin 210c, respectively.

The first angle (e.g., θ) between the third pin 210c location and the x-axis can be bound to the region between, for example, about −45° and 80°. The lower bound can be used to prevent the third pin 210c from interfering with the right pin 210a. The upper bound can be used to prevent over-constraint in the y-direction by, for example, maintaining a clearance between the vertical coordinate of the top of the sample 250 and the contact point between the sample 250 and the third pin 210c. The lower bound for the nesting force angle (e.g., ϕ) can be, for example, about 100° to prevent over-constraint, and the upper bound for the nesting force angle can be, for example, about 315° in order to prevent interference with the left pin 210b. Limiting the resulting moments to those with the appropriate orientation as shown in FIG. 5A can allow for the visualization of the nesting force window as a function of third pin angle θ. The results are shown in FIG. 6. Accordingly, when determining the optimal position for the third pin 210c and the preload device 225 according to the present disclosure, the restoring moments about the ICRs can be maximized as the first angle (e.g., θ) is moved towards its upper bound.

### EXAMPLES

### Example Computing Device

It should be appreciated that the logical operations described herein with respect to the various figures may be implemented (1) as a sequence of computer implemented acts or program modules (i.e., software) running on a computing device (e.g., the computing device described in FIG. 5), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 7, an example computing device 700 upon which embodiments of the invention may be implemented is illustrated. It should be understood that the technique for determining the optimal locations of the third pin and the preload device on the stage of the passive wafer alignment device can be implemented using a computing device such as computing device 700. It should also be understood that the example computing device 700 is only one example of a suitable computing environment upon which embodiments of the invention may be implemented. Optionally, the computing device 700 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 700 typically includes at least one processing unit 706 and system memory 704. Depending on the exact configuration and type of computing device, system memory 704 may be volatile (such as random access memory (RAM)), non-volatile (such as read-only memory (ROM), flash memory, etc.), or some combination of the two. This most basic configuration is illustrated in FIG. 7 by dashed line 702. The processing unit 706 may be a standard programmable processor that performs arithmetic and logic operations necessary for operation of the computing device 700. The computing device 700 may also include a bus or other communication mechanism for communicating information among various components of the computing device 700.

Computing device 700 may have additional features/functionality. For example, computing device 700 may include additional storage such as removable storage 708 and non-removable storage 710 including, but not limited to, magnetic or optical disks or tapes. Computing device 700 may also contain network connection(s) 716 that allow the device to communicate with other devices. Computing device 700 may also have input device(s) 714 such as a keyboard, mouse, touch screen, etc. Output device(s) 712 such as a display, speakers, printer, etc. may also be included. The additional devices may be connected to the bus in order to facilitate communication of data among the components of the computing device 700. All these devices are well known in the art and need not be discussed at length here.

The processing unit 706 may be configured to execute program code encoded in tangible, computer-readable media. Tangible, computer-readable media refers to any media that is capable of providing data that causes the computing device 700 (i.e., a machine) to operate in a particular fashion. Various computer-readable media may be utilized to provide instructions to the processing unit 706 for execution. Example tangible, computer-readable media may include, but is not limited to, volatile media, non-volatile media, removable media and non-removable media implemented in any method or technology for storage of information such as computer readable instructions, data structures, program modules or other data. System memory 704, removable storage 708, and non-removable storage 710 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 706 may execute program code stored in the system memory 704. For example, the bus may carry data to the system memory 704, from which the processing unit 706 receives and executes instructions. The data received by the system memory 704 may optionally be stored on the removable storage 708 or the non-removable storage 710 before or after execution by the processing unit 706.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

Prototype Design

A prototype passive wafer alignment device as shown in FIG. 2 was designed and fabricated to test the repeatability of the optimized design of the present disclosure. 5 mm dowel pins were press fit into a block of 6061 aluminum (e.g., the stage 200 of FIG. 2) to serve as constraints (e.g., the pins 210 of FIG. 2). The left pin and the right pin were permanently fixed such that they made contact with the wafer at a distance of 4 mm from the ends of the 32.5 mm flat on the wafer. Holes were drilled for the third pin at angles of −45, 0, 45, 70, and 80 degrees with respect to the x-axis. A prismatic flexure (e.g., the preload device 225 of FIG. 2) was designed to provide a nesting force of approximately 10 N to the wafer at an angle of 135 degrees with respect to the x-axis. The nesting force angle was selected to strike a balance between maximizing the restoring moments about ICRs and generating approximately equal reaction forces at each of the pins. The surface of the alignment mechanism is recessed so that the central axis of the flexure comes into contact with the wafer in order to minimize torsion.

Experimental Setup

The passive wafer alignment devices and methods provided here have many advantages over conventional technology. For example, the method provided herein can be used to effortlessly determine the ideal locations for a pin not on a flat and locations for a corresponding preload force (e.g., nesting force). The resulting pin and nesting force locations have been experimentally proven to improve the repeatability of wafer positioning.

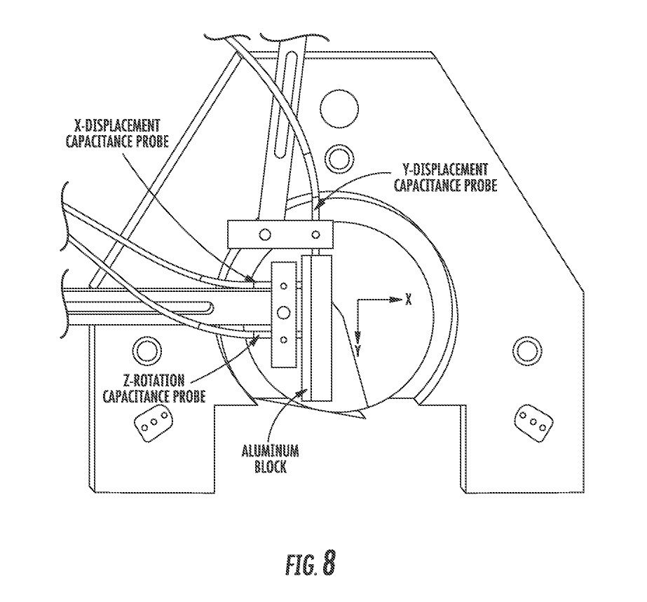

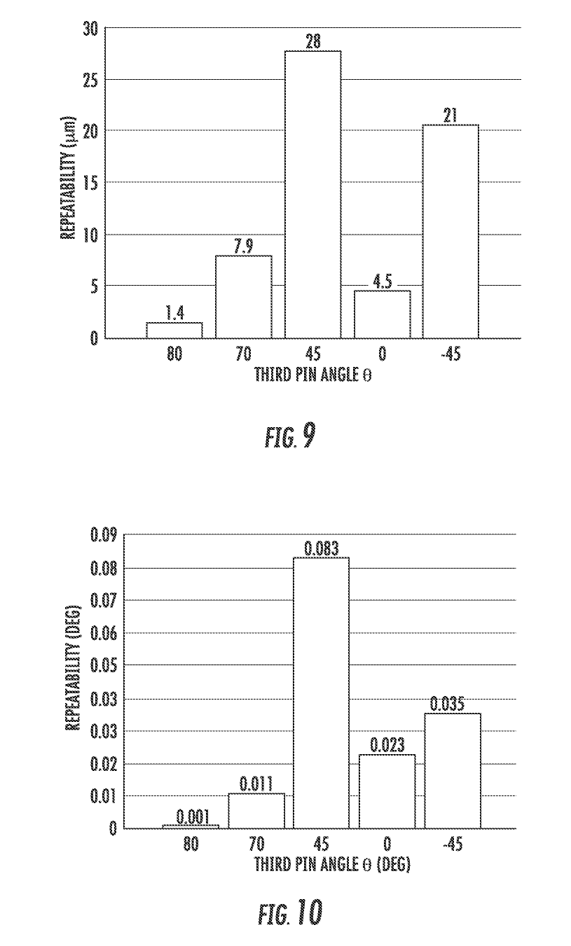

Referring now to FIG. 8, an experimental testing setup using the prototype passive wafer alignment device described above is shown. The following experiments were performed using the experimental setup of FIG. 8 to determine wafer placement repeatability as a function of third pin angle θ. Lateral repeatability was determined by measuring the distance from three capacitance probes to a reference block of aluminum bonded to a silicon wafer. Two capacitance probes separated by a known distance and with faces parallel to one face of the block measured translational repeatability in the x-direction and rotational repeatability about the z-axis. Translational repeatability in the y-direction was measured with an additional capacitance probe orthogonal to the two in the x-direction. On the first placement of the wafer, the capacitance probe measured distances were nulled such that each additional measurement was made relative to the first measurement. Between measurements the wafer was completely removed from the stage and then carefully hand-placed back on the stage. For each experiment fifty measurements were recorded with the maximum and minimum values discarded. Repeatability was defined as the standard deviation of the trials. The square root of the sum of the squares of repeatability in the x and y directions was used as a measure of overall lateral repeatability.

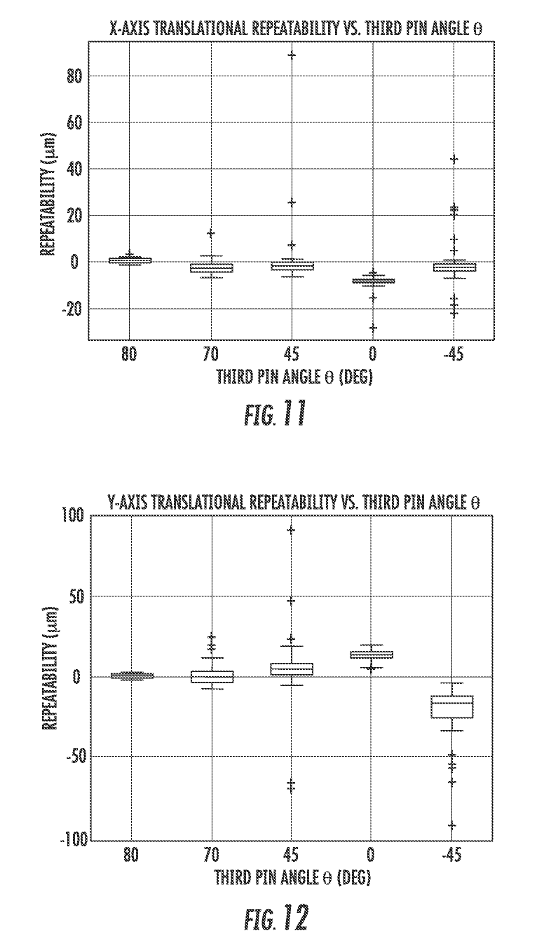

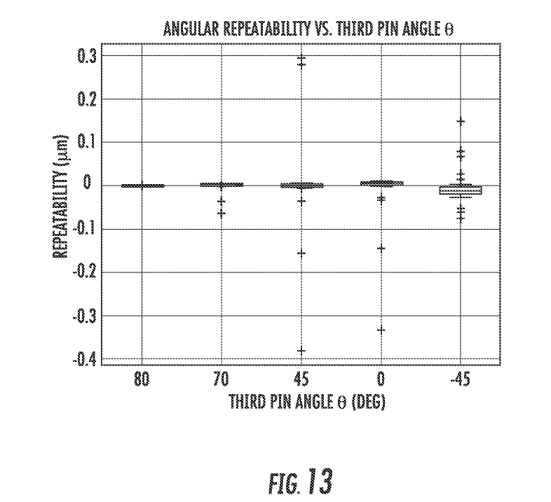

Optimal repeatability was achieved with a coupling configuration that maximized the moments about the instantaneous centers of rotation. As shown in FIG. 9, positioning the third pin at an angle of 80° resulted in translational repeatability of 1.4 μm. Repeatability of other pin locations was skewed by a number of outliers with positioning errors that are an order-of-magnitude greater than the mean. FIGS. 11, 12, and 13 give insight into the distribution of the repeatability data. The boxes bound results that fall between the 25th percentile (Q1) and 75th percentile (Q3) values of sample data. Median values for each pin location are indicated by a red line within the boxes. Statistical outliers are shown as crosses and are values that are greater than Q3+1.5*(Q3−Q1) or smaller than Q1−1.5*(Q3−Q1). In a number of cases rotation about the x and y axis was observed and an additional experiment was performed that identified the efficacy of tapering two of the pins to constrain rotational degrees of freedom.

Thus, as described above, disclosed herein are passive wafer alignment devices and methods for improving the repeatability of a passive alignment mechanism, which can be embodied as a silicon wafer alignment device. While the example passive alignment device disclosed herein can be used to successfully align 100 mm silicon wafers, the method itself is an advancement of principles in exact constraint design. As such, the passive wafer alignment devices and methods disclosed herein can be used to align other suitable sizes of wafers and can also be useful for designing fixtures for other suitable mechanisms. The passive wafer alignment devices and methods disclosed herein can be applied to other systems, for example, a system designed to constrain a cylindrical object with a flat. The passive wafer alignment devices and methods can also be used to maximize the repeatability of a pin-based fixture constraining of any object so long as two pins are in contact with an edge on the object.

Advantages

Conventional alignment technologies mention that the third pin can be located so that the nesting force produces a substantial restoring moment about the instantaneous centers of the pins. In addition, literature on the subject of alignment suggests that the moment of the nesting force about each instantaneous center formed by two pins should be in the direction of the remaining pin. However, neither the literature nor conventional technology provide any detail on the precise location of the third pin or the nesting force, and much less a method for making such a determination.

The passive wafer alignment devices and methods disclosed herein use an algorithm that determines the exact location at which the nesting force moment is maximized and is in the proper direction. The technique for determining the location of the pins and the nesting force is unique in that it provides a single solution for both the location of one pin (e.g. The third pin) and the nesting force (e.g., the preload device).

The passive wafer alignment devices and methods disclosed herein has many advantages over conventional technology. For example, the algorithm described herein can be used to effortlessly determine the ideal locations for the pin not on the wafer flat (e.g., the third pin) and the nesting force (e.g., the preload device). The algorithm can also be applied to different applications and is limited only by the condition that two of three restraining pins lie on a straight edge of the object to be restrained. The resulting pin and nesting force locations have been experimentally proven to improve the repeatability of wafer positioning.

Another advantage of the passive wafer alignment devices and methods disclosed herein over conventional technologies is that it prevents significant sources of misalignment errors before they happen. The design uses a flexural bearing or spring to apply the nesting force or preload force. The flexure is adjustable so that the force applied to the wafer can be known with certainty. This prevents errors such as the wafer shattering from excessive force or inconsistencies in position due to varying deflections in the wafer pin contact interface. The double parallelogram flexure design also ensures that the force is consistently applied perpendicular to the flat face of the wafer. This prevents jamming and out of plane misalignment.

Another advantage of the passive wafer alignment devices and methods disclosed herein is the use of tapered pins a. These pins assist in preventing out of plane alignment that other technologies do not consider. The passive wafer alignment devices and methods disclosed herein address this problem of conventional technologies by constraining all degrees of freedom of the wafer. It is neither over constrained nor under constrained. The mechanism is designed to reduce the chances of becoming over or under constrained. In addition, the mechanism corrects small initial alignment errors when the wafer is placed on the stage so that the wafer always has a tendency to be in contact with three pins.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A passive wafer alignment device, comprising:
a stage for holding a wafer;
a plurality of pins arranged on the stage, the pins being arranged to contact respective portions of the wafer; and
a preload device arranged on the stage, the preload device being configured to apply a preload force to the wafer, wherein:
two of the pins are arranged to contact respective portions of a flat edge of the wafer,
a third pin and the preload device are arranged to contact respective portions of a curved edge of the wafer, and
the third pin and the preload device are arranged at respective locations on the stage to optimally constrain the wafer to the stage.

2. The passive wafer alignment device of claim 1, wherein the respective locations on the stage for the third pin and the preload device optimize a restoring moment about an instantaneous center of rotation (ICR) imposed by the preload force on the wafer.

3. The passive wafer alignment device of claim 2, wherein the respective locations on the stage for the third pin and the preload device maximize the restoring moment about the ICR imposed by the preload force on the wafer.

4. The passive wafer alignment device of claim 3, wherein the restoring moment is maximized as a function of a first angle formed between an axis of the wafer and the respective location of the third pin.

5. The passive wafer alignment device of claim 2, wherein the ICR imposed by the preload force on the wafer comprises an intersection point between a line of action associated with the third pin and a line of action associated with one of the two pins.

6. The passive wafer alignment device of claim 5, wherein a line of action is defined by a respective direction of a reaction force at a pin.

7. The passive wafer alignment device of claim 6, wherein respective lines of actions associated with the two pins are approximately parallel.

8. The passive wafer alignment device of claim 1, wherein the pins are tapered.

9. The passive wafer alignment device of claim 1, wherein the preload device is a flexural bearing.

10. A passive wafer alignment device, comprising:
a stage for holding a wafer;
a plurality of tapered pins arranged on the stage, the tapered pins being arranged to contact respective portions of the wafer; and
a preload device arranged on the stage, the preload device being configured to apply a preload force to the wafer.

11. The passive wafer alignment device of claim 10, wherein the tapered pins are configured to constrain the wafer to the stage via surface-to-surface contact.

12. A passive wafer alignment device, comprising:
a stage for holding a wafer;
a plurality of pins arranged on the stage, the pins being arranged to contact respective portions of the wafer; and
a flexural bearing arranged on the stage, the flexural bearing being configured to apply a preload force to the wafer.

13. The passive wafer alignment device of claim 12, wherein the flexural bearing defines a circular contact interface.

14. The passive wafer alignment device of claim 12, wherein the flexural bearing is further configured to adjust the preload force applied to the wafer.

15. A method for producing a passive wafer alignment device, comprising:
arranging a plurality of pins on a stage for holding a wafer, wherein two of the pins are arranged to contact respective portions of a flat edge of the wafer;
determining respective optimal locations on the stage for a third pin and a preload device for applying a preload force to the wafer; and
arranging the third pin and the preload device at the respective optimal locations on the stage, wherein the third pin and the preload device are arranged to contact respective portions of a curved edge of the wafer.

16. The method of claim 15, wherein determining respective optimal locations on the stage for a third pin and a preload device further comprises analyzing a plurality of reaction forces at each of the pins as a function of a first angle formed between an axis of the wafer and the respective optimal location of the third pin and a second angle formed between the axis of the wafer and the respective optimal location of the preload device.

17. The method of claim 16, wherein determining respective optimal locations on the stage for a third pin and a preload device further comprises determining values of the first angle and the second angle that result in compressive reaction forces at the pins.

18. The method of claim 15, wherein determining respective optimal locations on the stage for a third pin and a preload device further comprises analyzing a restoring moment about an instantaneous center of rotation (ICR) imposed by the preload force on the wafer.

19. The method of claim 18, wherein determining respective optimal locations on the stage for a third pin and a preload device further comprises maximizing the restoring moment about the ICR imposed by the preload force on the wafer.

20. The method of claim 19, wherein the restoring moment is maximized as a function of a first angle formed between an axis of the wafer and the respective optimal location of the third pin.

21. The method of claim 18, wherein the ICR imposed by the preload force on the wafer comprises an intersection point between a line of action associated with the third pin and a line of action associated with one of the two pins.

22. The method of claim 21, wherein a line of action is defined by a respective direction of a reaction force at a pin.

23. The method of claim 22, wherein respective lines of actions associated with the two pins are approximately parallel.

24. The method of claim 15, wherein the pins are tapered.

25. The method of claim 24, wherein the pins are configured to constrain the wafer to the stage via surface-to-surface contact.

26. The method of claim 15, wherein the preload device comprises a flexural bearing.

27. The method of claim 26, wherein the flexural bearing defines a circular contact interface.

28. The method of claim 15, wherein the preload device is further configured to adjust the preload force applied to the wafer.
